(19) United States
(12) Patent Application Publication
(10) Pub. No.: US 2013/0206589 A1
(43) Pub. Date: Aug. 15, 2013

(54) Sputtering Target Having Alarm Function

(71) Applicants: Shu-Hua Hu, Tainan (TW); Ming-Chang Lu, Tainan (TW); Pai-Ying Su, Tainan (TW); Jung-Sheng Chen, Tainan (TW); Hsin-Chun Yin, Tainan (TW)

(72) Inventors: Shu-Hua Hu, Tainan (TW); Ming-Chang Lu, Tainan (TW); Pai-Ying Su, Tainan (TW); Jung-Sheng Chen, Tainan (TW); Hsin-Chun Yin, Tainan (TW)

(73) Assignee: Solar Applied Materials Technology Corp., Tainan (TW)

(21) Appl. No.: 13/372,579

(22) Filed: Feb. 14, 2012

(51) Int. Cl. C23C 14/54; C23C 14/34

(52) U.S. Cl. 204/298.12

(57) ABSTRACT

The present invention provides a sputtering target having alarm function. The sputtering target comprises: a target body including a target material and having a bonding plane; a backing body bonded with the bonding plane of the target body; and at least one alarm body embedded in the target body. Wherein, a length of each alarm body, ratios of an area of each alarm body and the sum of area(s) of the at least one alarm body projected onto the bonding plane relative to an area of the bonding plane are controlled in a suitable range. Thus, the bonding strength and the heat-removing efficiency of the sputtering target can be maintained, and the distinguishable material of the alarm body can evolve a gas component distinguishable from a sputtering environment serving as an alarm signal for stopping the sputtering process in time.

### BACKGROUND OF THE INVENTION

1. Field of the Invention

The present invention relates to a sputtering target having alarm function, and particularly to a sputtering target comprising alarm bodies for producing alarm signals for stopping sputtering process.

2. Description of the Prior Arts

Physical vapor deposition, PVD, is a conventional coating method for forming films, wherein atoms or molecules are physically deposited onto a substrate such as metal substrate, alloy substrate, ceramic substrate, and silicon wafer substrate, etc, and then a film is formed on the substrate.

Physical vapor deposition is classified into evaporation deposition and sputtering deposition. With the glow discharge effect, the inert gas is ionized and then bombards the surface of target, and the atoms or molecules of targets will be struck out and then deposited onto the substrate, and finally form a uniform film. Hence, physical vapor deposition becomes the most common film-forming technology in the semiconductor, photoelectric, or storage media field.

The sputtering target, which is composed of target and a backing plate, is the indispensable material during the sputtering process. Because the backing plate is mostly made of good thermal-conductivity material and has fine internal channel design for water-cooling, it can be the important component for heat-removing and loading the target to the sputtering machine. However, the production cost of the backing plate is too expensive. Therefore, if the backing plate can be separated from the sputtered target after sputtering the target, and the backing plate can be recycled and reused after being suitably cleaned, then the cost of sputtering process can be largely reduced by recycling and reusing the backing plate.

Hence, in order to maintain the integrity of the backing plate, the sputtering process is usually stopped before the target is eroded completely and the target is immediately replaced by a new one. However, while replacing target, the whole vacuum chamber has to be vented, thus leading to destruction of the vacuum. If the time point of replacing the target is too early, the production capacity per equipment and usage of target will be reduced. If the time point of replacing the target is too late, the risk of damaging backing plate will be raised. Thus, how to replace the target disposed on the backing plate in time becomes a very important issue.

Many researches on how to detect the usage of sputtering target have been developed recently. As disclosed by U.S. Pat. No. 5,487,823, a distinguishable material is placed between the target and the backing plate of the sputtering target. When the target is eroded to a certain depth, the usage of the target can be detected by recognizing the gas, which is produced by the distinguishable material. However, said patent is completely silent to a preferable ratio of the area of the distinguishable material to the area of the whole target. The bonding strength of the target to the backing plate and the performance of sputtering target are deteriorated by the existence of distinguishable material, and the economic effects of the target material cannot be improved effectively.

Accordingly, in order to overcome the afore-mentioned problems, the present invention provides a sputtering target having alarm function, which can produce alarm signals after the target is sputtered to the deepest depth of the erosion profile and before the backing plate is damaged, in order to ensure the usage of the target and the integrity of the backing plate. On the basis of not deteriorating the properties of sputtering target, the sputtering target in accordance with the present invention can produce alarm signals to stop the sputtering process and thus improving the performance of the sputtering target during the sputtering process, and thereby the cost of sputtering process can be largely reduced.

### SUMMARY OF THE INVENTION

The primary objective of the present invention provides a sputtering target having alarm function, which can maintain the bonding strength of the target body to the backing body, and the alarm body of the sputtering target can evolve a gas as alarm signals to stop the sputtering process in time, so that the integrity of the backing body can be maintained and the cost of the sputtering process can be reduced as well.

To achieve the afore-mentioned objective, the present invention provides a sputtering target having alarm function, comprising: a target body including a target material and having a bonding plane; a backing body bonded with the bonding plane of the target body; and at least one alarm body embedded in the target body, wherein a length of each alarm body is more than 1 centimeter (cm), a percentage of an area of each alarm body projected onto the bonding plane relative to an area of the bonding plane is less than or equal to 1%, and a percentage of the sum of area(s) of the at least one alarm body projected onto the bonding plane relative to the area of the bonding plane is less than or equal to 20%; wherein the at least one alarm body contains a distinguishable material, and the distinguishable material evolves a gas component distinguishable from a sputtering environment and the target material while being subjected to the sputtering environment.

When the target body is eroded to the depth of the alarm body in the sputtering process, the distinguishable material of the alarm body will evolve a gas component distinguishable from the sputtering environment and the target material. When the gas component is detected by the gas analyzer, the detection of the gas component will transform to an alarm signal for stopping the sputtering process, and then the alarm signal prevents the backing body from being damaged by plasma.

Preferably, the at least one alarm body of the sputtering target having alarm function in accordance with the present invention is disposed at the region of the target body being eroded first. In addition, the deviation of the erosion profile between different sputtering targets in the same equipment can be controlled within 1 centimeter. Thus, in order to prevent the disparity of location between the erosion position and the alarm body, the length of each alarm body is preferably more than 1 centimeter. However, if the sum of area(s) of the at least one alarm body projected onto the bonding plane is too large, the target body cannot have enough bonding strength to bond with the backing body, and thereby the sputtering quality of the sputtering target will be reduced. Thus, the percentage of the sum of area(s) of the at least one alarm body projected onto the bonding plane relative to the area of the bonding plane should be less than or equal to 20%. In addition, if the percentage of the area of each single alarm body projected onto the bonding plane relative to the area of the bonding plane is more than 1%, the local heat-removing efficiency of the backing body of the sputtering target will be reduced, and furthermore the property of film will be deteriorated. Thus, in order to ensure the local efficiency of the sputtering target, the percentage of the area of each alarm body projected onto the bonding plane relative to the area of the bonding plane should be less than or equal to 1%. The bonding strength and heat-removing efficiency of the sputtering target in accordance with the present invention can be maintained and the possibility of target body being detached from the backing body can be prevented because the sum of the area(s) of the at least one alarm body projected onto the bonding plane is controlled within a suitable range.

Preferably, the at least one alarm body of the sputtering target in accordance with the present invention may be coated and filled with the distinguishable material, or the distinguishable material of the at least one alarm body may be separately distributed continuously or discontinuously.

The distinguishable material of alarm body of the sputtering target having alarm function in accordance with the present invention can be made of semiconductor compounds or metal compounds, such as ceramic materials, nitrides, oxides, metal, alloy, or metal oxides, etc. Preferably, the distinguishable material is AN, BN, SiC, Al₂O₃, Si₃N₄, ZrO₂, MgO, or Li₂O.

In addition, the backing body of the sputtering target having alarm function in accordance with the present invention can be a backing plate or a backing tube. If the backing body is a backing plate, the target body can be made in a plate structure and is bonded with the backing plate on a flat surface. If the backing body is a backing tube, the target body can be made in a hollow cylinder structure having an interior space, and the backing body is disposed at the interior space of the hollow target body and has an arc surface, wherein the arc surface is bonded with the target body.

Another objective of the present invention provides a sputtering target having alarm function, wherein the at least one alarm body is disposed on the bonding plane of the target body. Because the target body of the sputtering target is eroded to a similar erosion profile and the sputtering process has a good reproducibility by using the same one sputtering equipment, the at least one alarm body is preferably disposed at the region of the target body being eroded first and projected onto the bonding plane, so that the alarm function of the sputtering target in accordance with the present invention will be assured, and thereby the usage of the target body can be improved and the backing body will not be eroded.

Because each alarm body of the sputtering target in accordance with the present invention is embedded in the target body beneath the erosion profile formed on the target body during the sputtering process, the gas component for stopping the sputtering process is evolved until the erosion profile reaches a predetermined depth, so that the usable erosion depth of the target body will be maximized and the usage of the target body is ultimately enhanced. Thus, the frequency of replacing the target body during the sputtering process will be reduced, and then the production efficiency of the sputtering process will be improved.

Accordingly, the length of each alarm body of the sputtering target in accordance with the present invention is controlled to be more than 1 centimeter, the percentage of the area of each alarm body projected onto the bonding plane relative to an area of the bonding plane is less than or equal to 1%, and the percentage of the sum of area(s) of the least one alarm body projected onto the bonding plane relative to the area of the bonding plane is less than or equal to 20%, so that the bonding strength of target body to the backing body and the heat-removing efficiency of the backing body can be ensured. Furthermore, the erosion depth of the sputtering target in accordance with the present invention is maximized, and the production efficiency of the sputtering process by using the sputtering target in accordance with the present invention will be ultimately improved.

Other objectives, advantages and novel features of the invention will become more apparent from the following detailed description when taken in conjunction with the accompanying drawings.

### BRIEF DESCRIPTION OF THE DRAWINGS

FIG. 1 is a cross-sectional side view of the sputtering target in accordance with Embodiment 1 of the present invention;

FIG. 2 is a perspective view of the sputtering target in accordance with Embodiment 1 of the present invention;

FIG. 3 is a graph showing the dependency of the partial pressure of the boron nitrides on the sputtering time;

FIG. 4 is a cross-sectional side view of the sputtering target in accordance with Embodiment 2 of the present invention;

FIG. 5 is a perspective view of the sputtering target in accordance with Embodiment 2 of the present invention;

FIG. 6 is a plan view of a distribution of single alarm body in accordance with the present invention; and

FIG. 7 is a plan view of another distribution of single alarm body in accordance with the present invention.

### DETAILED DESCRIPTION OF THE PREFERRED EMBODIMENTS

In order to prevent the backing body of the sputtering target from being damaged by plasma, the present invention develops a sputtering target, incorporating the conventional target and at least one alarm target to make the sputtering targets in accordance with the present invention have alarm function. Besides, in order to ensure the bonding strength of the target body to the backing body and the heat-removing efficiency of the backing body, the present invention further discloses the limitation of disposing the at least one alarm body to produce a sputtering target with good properties.

As described by the sputtering target in accordance with the present invention, the target body of the present invention includes a target material comprising metals such as, but not limited to, aluminum, tungsten, molybdenum, titanium, tantalum, alloy, or silicide. The at least one alarm body of the present invention includes a distinguishable material such as, but not limited to, AlN, BN, SiC, Al₂O₃, Si₃N₄, ZrO₂, MgO, or Li₂O. Because the distinguishable material can evolve a gas component which is distinguishable from a sputtering environment and the target material while being subjected to the sputtering environment, the specific gas component evolved by the target body can be detected by way of analyzing the specific molecular weights detected by a gas analyzer or by way of analyzing the specific lines and intensities of an optical emission spectroscopy. Thus, when the gas component evolved by the distinguishable material is detected through the afore-mentioned method, the detection of the gas component can serve as an alarm signal for stopping the sputtering process and prevent the backing body of the sputtering target from being damaged by plasma.

### Embodiment 1

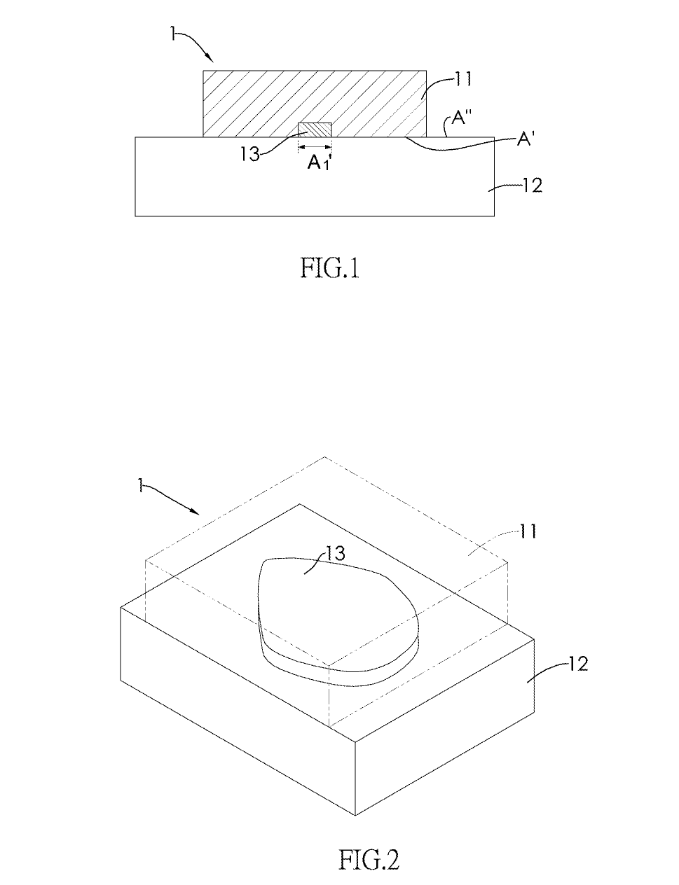

With reference to FIG. 1 and FIG. 2, the sputtering target having alarm function 1 of the present invention comprises: a target body 11 including a target material and having a bonding plane A′; a backing body 12 bonded with the bonding plane A′ of the target body 11; and an alarm body 13 is filled with the distinguishable material and coated onto the bonding plane A′ of the target body 11.

In Embodiment 1, a percentage of an area of the alarm body 13 projected onto the bonding plane A₁′ relative to an area of the bonding plane A′ is less than or equal to 20%. As shown by the present embodiment, the area of the alarm body 13 projected onto the bonding plane A′ is equal to the area of the alarm body 13 in contact with the top face A″ of the backing body 12. If the projection area A₁′ of the alarm body 13 is controlled within a suitable range, the bonding strength of the target body 11 to the backing body 12 and the heat-removing efficiency of the backing body 12 can be maintained, and then the possibility of the target body 11 being detached from the backing body 12 can be reduced during the sputtering process.

In the sputtering target of the present embodiment, the target body includes a target material, which is aluminum, and the alarm body includes a distinguishable material, which is boron nitride. The distinguishable material can evolve boron nitride molecules, which are distinguishable from the gas components in a sputtering environment and the target materials while being subjected to the sputtering environment. Then, the gas analyzer can analyze the partial pressure of boron nitrides evolved by the distinguishable material, wherein the molecule weights of boron nitrides are about 24 Da and 25 Da.

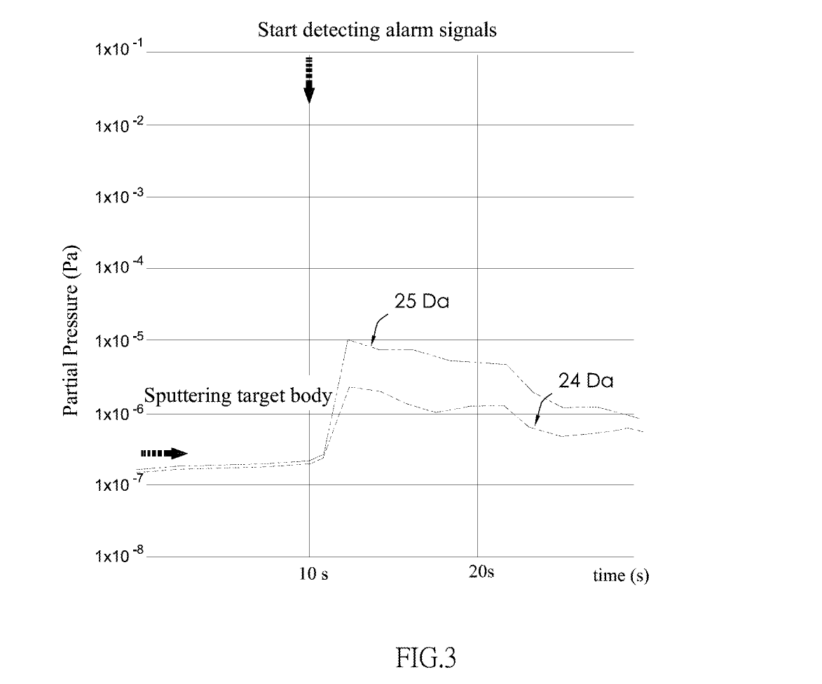

Accordingly, when the target body of the sputtering target in accordance with the present invention is eroded to the position where the at least one alarm body is disposed, the distinguishable material of the alarm body will evolve the gas component distinguishable from a sputtering environment and the target material while being subjected to the sputtering environment. As shown by the down arrow in FIG. 3, a gas detector starts detecting the alarm signals for stopping the sputtering process produced by the distinguishable material.

With reference to FIG. 3, the right arrow represents the process of sputtering the target body continuously. The period of sputtering process varies depending on the thickness of the target body. With reference to FIG. 3, the partial pressure of boron nitrides, whose molecular weights are 24 Da and 25 Da, is significantly raised until the target body is eroded to the depth of the alarm body. In the present embodiment, 10⁻⁵ to 10⁻⁶ Pa of the partial pressure indicates that the erosion depth of the sputtering target in accordance with the present invention is maximized.

Thus, when the gas component evolved by the distinguishable material is detected by the afore-mentioned method, the sudden rise of the partial pressure of gas component evolved by the distinguishable material can serve as an alarm signal to stop the sputtering process, and thereby the backing body of the sputtering target in accordance with the present invention will not be damaged by plasma.

### Embodiment 2

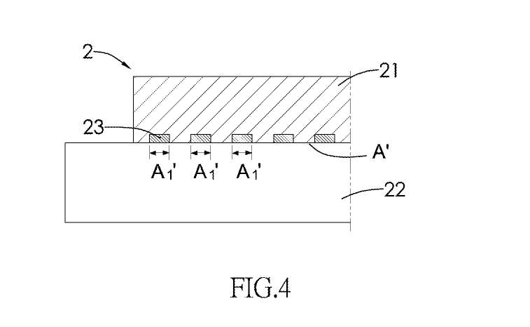

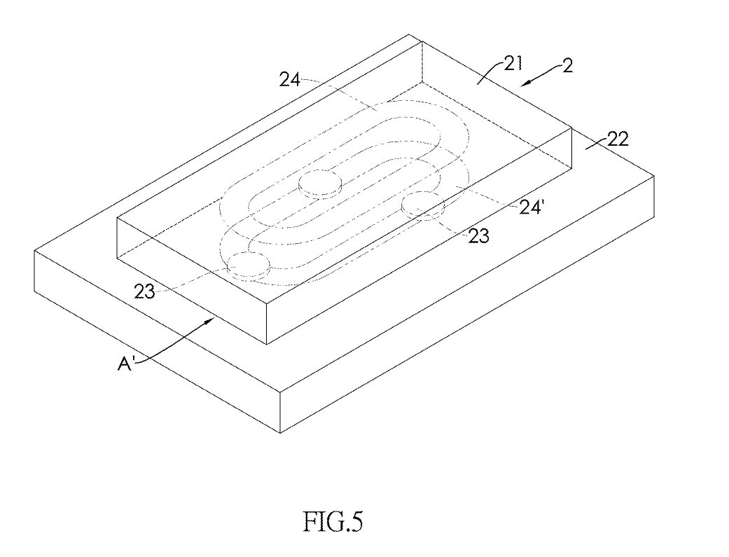

With reference to FIGS. 4 and 5, the sputtering target having alarm function 2 in accordance with the present invention comprises multiple alarm bodies 23.

As described by the Embodiment 1, the sputtering target having alarm function 2 of the present embodiment comprises: a backing body 22, and a target body 21 disposed on the backing body 22. Wherein, the target body 21 has a bonding plane A′, and the backing body 22 is bonded with the bonding plane A′ of the target body 21.

The difference between Embodiments 1 and 2 is that the sputtering target 2 of the present embodiment comprises multiple alarm bodies 23, and the multiple alarm bodies 23 are disposed at where the erosion profile of the target body 21 is projected onto the bonding plane A′. With reference to FIG. 5, the predetermined erosion profile 24 of the target body 21 sputtered by using a sputtering equipment is mapped on the target body 21 in advance. Each of the multiple alarm bodies 23 will be disposed at the region of the multiple alarm bodies 24′, wherein the region of the multiple alarm bodies 24′ is a region of the predetermined erosion profile 24 of the target body 21 projected onto the bonding plane A′.

In the present embodiment, a percentage of the area of each alarm body 23 projected onto the boding plane A₁′ relative to the area of the bonding plane A′ is less than or equal to 1%, so that the local heat-removing efficiency of sputtering target in accordance with the present invention can be maintained. The percentage of the sum of areas of the multiple alarm bodies 23 projected onto the bonding plane A₁′ relative to the area of the bonding plane A′ is less than or equal to 20%. Besides, the length L of each alarm body 23 is also controlled to be more than 1 centimeter.

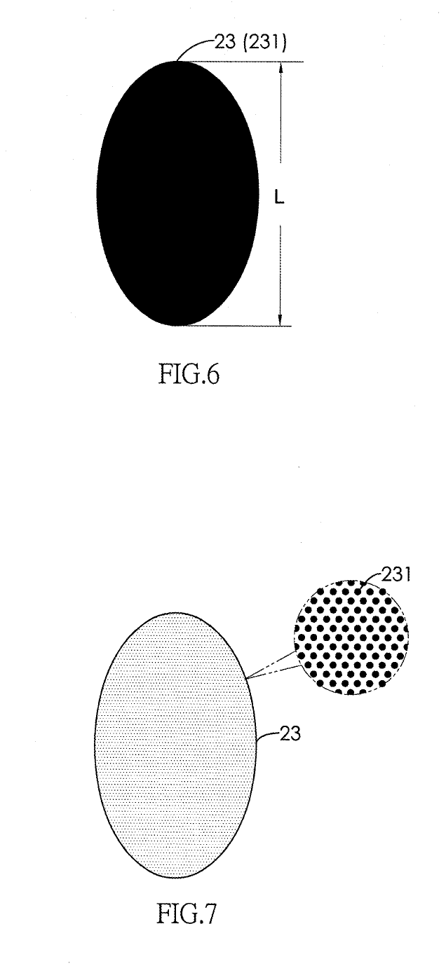

With reference to FIG. 6, the possibility of damaging the backing body caused by the disparity of location between the erosion position and the alarm bodies can be prevented if the length of each alarm body is controlled to be more than 1 cm.

In addition, each alarm body 23 may be filled with the distinguishable material 231 as shown in FIG. 6, or the distinguishable material 231 of each alarm body 23 may be separately distributed continuously or discontinuously as shown in FIG. 7.

In summary, the sputtering targets having alarm function in accordance with the present invention control the percentage of the area of the at least one alarm body in contact with the backing plate relative to the area of the bonding plane, so that a sputtering target having alarm function, good performance and heat-removing efficiency can be produced.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A sputtering target having alarm function, comprising:
a target body including a target material and having a bonding plane;
a backing body bonded with the bonding plane of the target body; and
at least one alarm body embedded in the target body, wherein a length of each alarm body is more than 1 centimeter(cm), a percentage of an area of each alarm body projected onto the bonding plane relative to an area of the bonding plane is less than or equal to 1%, and a percentage of the sum of area(s) of the at least one alarm body projected onto the bonding plane relative to the area of the bonding plane is less than or equal to 20%;
wherein the at least one alarm body contains a distinguishable material, wherein the distinguishable material evolves a gas component distinguishable from a sputtering environment and the target material while being subjected to the sputtering environment.

2. The sputtering target having alarm function according to claim 1, wherein the backing body is a backing plate or a backing tube.

3. The sputtering target having alarm function according to claim 1, wherein the at least one alarm body is embedded in the target body and filled with the distinguishable material.

4. The sputtering target having alarm function according to claim 1, wherein the at least one alarm body is embedded in the target body, and the distinguishable material of the at least one alarm body is separately distributed.

5. The sputtering target having alarm function according to claim 1, wherein the distinguishable material is AlN, BN, SiC, Al₂O₃, Si₃N₄, ZrO₂, MgO, or Li₂O.

6. The sputtering target having alarm function according to claim 1, wherein the at least one alarm body is disposed onto the target body.

7. The sputtering target having alarm function according to claim 1, wherein the at least one alarm body is disposed at a position where an erosion profile of the target body is projected onto the bonding plane.
